(19) United States
(12) Patent Application Publication
(10) Pub. No.: US 2025/0089555 A1
(43) Pub. Date: Mar. 13, 2025

(54) PROCESS FOR PRODUCING AN ORGANIC-INORGANIC HYBRID PEROVSKITE LAYER OF CONTROLLED COMPOSITION

(71) Applicant: Commissariat à l'Énergie Atomique et aux Énergies Alternatives, Paris (FR)

(72) Inventors: Louis Grenet, Grenoble (FR); Elodie Testard, Grenoble (FR); Frédéric Roux, Grenoble (FR)

(73) Assignee: Commissariat à l'Énergie Atomique et aux Énergies Alternatives, Paris (FR)

(21) Appl. No.: 18/826,714

(22) Filed: Sep. 6, 2024

(30) Foreign Application Priority Data
Sep. 12, 2023 (FR) 2309596

(51) Int. Cl. H10K 85/50; C07F 7/24; C23C 8/34; H10K 30/40; H10K 30/57; H10K 71/10

(52) U.S. Cl. CPC H10K 85/50; C07F 7/24; C23C 8/34; H10K 30/57; H10K 30/40; H10K 71/10

(57) ABSTRACT

A process for producing an organic-inorganic perovskite layer including the following steps: Forming of a layer of inorganic precursors on a substrate, Implementation of a step of close space sublimation from a powder including the organic precursors, whereby the vapors from the layer of organic precursors react with the layer of inorganic precursors and a hybrid organic-inorganic perovskite layer is formed, the powder of organic precursors being obtained by mechanosynthesis by co-grinding at least a first group of particles of a first material and a second group of particles of a second material to form a third group of particles of a third material, the third group of particles forming the powder of organic precursors.

### CROSS REFERENCE TO RELATED APPLICATIONS

This application claims priority to French application number 2309596, filed Sep. 12, 2023. The contents of this application are incorporated by reference in its entirety.

### TECHNICAL FIELD

The present disclosure generally concerns the field of hybrid organic-inorganic perovskites, and more particularly their production process.

The invention has applications in many industrial fields, in particular in the photovoltaic field, or also for the manufacturing of electronic, optical, or optoelectronic devices, in particular for the manufacturing of light-emitting diodes (LEDs), of photodetectors, of scintillators, of X-ray detectors for example for medical applications or also of transistors.

The invention is particularly advantageous in that it enables to form perovskite layers having a controlled composition with relatively short deposition times.

### PRIOR ART

Hybrid organic-inorganic perovskites are particularly advantageous materials for photovoltaic cells, and in particular for tandem photovoltaic cells on silicon.

Among particularly promising organic-inorganic hybrid materials, material of ABX₃ type, with A representing a cation or a mixture of cations selected from among Cs⁺, FA⁺ (with FA=CH₅N₂), MA⁺ (with MA=CH₃—NH₃), B a metal cation selected from among Pb, Sn, Ge, and X a halogen selected from among Cl, Br, and I, can be mentioned.

Generally, hybrid perovskite layer production processes are carried out in two steps: the inorganic part of the perovskite is deposited first, and is then reacted with the organic part to form the perovskite.

For example, in the article by Sahli et al. (Nature Materials 2018, 17, 820826), a layer of perovskite material of formula CsₓFA₁₋ₓPb(I,Br)₃ is obtained by first forming a porous layer by co-evaporation of lead iodide (PbI₂) and of cesium bromide (CsBr). Then, an organohalide solution comprising formamidinium iodide (FAI) and formamidinium bromide (FABr) is deposited by spin-coating. After an anneal at 150° C. in ambient air, the perovskite is crystallized.

In the paper by Zhang et al. (ACS Appl. Energy Mater. 2022, 5, 5797-5803), Cs_{0.14}FA_{0.86}Pb(BrₓI₁₋ₓ)₃ films are also obtained by implementing a process in two steps. In a first step, inorganic CSI and PbI₂ layers are sequentially deposited on a substrate. In a second step, an organic FAI film or an organic FAI/FABr film is prepared by depositing by sputtering an ethanol solution comprising the precursors. This film is used to implement a step of close space sublimation (CSS) at a 160° C. temperature. During this step, the material is sublimated, which enables to react the organic vapors with the CSI and PbI₂ layers and thus to form the perovskite material.

In CSS processes, it is also known that it is possible to use a precursor powder, for example in the form of a solid wafer (target). Such a process is easy to implement when there is a single precursor. However, in the case where there are two different precursors, for example FAI particles and FABr particles, the process is more difficult to implement.

Indeed, the maximum acceptable temperature in a CSS process must be lower than the melting temperature of the target. Now, the melting temperature of FAI is 242° C. and that of FABr is 135° C. Thus, above 125° C., a partial melting of the target and/or the bonding to the susceptor can be observed.

Moreover, if the working temperature is too low, reaction kinetics are slower and the duration of the process may be considerably extended.

Further, since the sublimation of FABr occurs at a lower temperature than that of FAI, the FABr/FAI ratio in the atmosphere is higher than that of the target, which results in two major problems. First, the control of the quantity of the FABr/FAI ratios in the target to achieve the desired Br content in the perovskite is difficult to determine, since the FABr/FAI ratio in the atmosphere is different from that in the target.

Second, the composition of the target changes over time, since FABr sublimates preferentially over FAI, which modifies the FABr/FAI ratio in the target over time. The deposited material thus has neither a homogeneous composition nor the desired composition.

### SUMMARY OF THE INVENTION

There thus exists a need to obtain a process enabling to form a hybrid organic-inorganic perovskite layer having a controlled composition.

This aim is achieved by a process for producing an organic-inorganic perovskite layer comprising the following steps:
Forming of a layer of inorganic precursors on a substrate,
Implementation of a short-distance sublimation step from a powder of organic precursors, whereby the vapors of the powder of organic precursors react with the layer of inorganic precursors and a layer of organic-inorganic hybrid perovskite is formed,
the organic precursor powder being obtained by mechanosynthesis, by co-grinding at least a first group of particles of a first material and a second group of particles of a second material, until forming a third group of particles of a third material, the third group of particles forming the powder of organic precursors.

The invention fundamentally differs from prior art in that the second process step is carried out with a powder of inorganic precursors obtained by mechanosynthesis.

The powder obtained by mechanosynthesis comprises particles having a composition corresponding to the composition which is desired to be reacted with the previously-deposited layer of inorganic precursors. The particles are preferably single-phase.

Thus, when the third material is sublimated at step b), the vapors of the third material react with the layer of inorganic precursors to form the perovskite.

The use of particles obtained by mechanosynthesis is particularly advantageous from an industrial point of view because, since the particles forming the powder all have the same composition, this enables to increase the temperature of the CCS step and thus to decrease the duration of this step.

For example, the melting temperature of FA(I_{1-y}Br_{y}) is between that of FAI and FABr.

Further, the vapors generated during the CCS step have the same composition all the time, because the composition of the target remains constant during the process. The perovskite material thus formed is homogeneous and has the desired composition.

Advantageously, the hybrid organic-inorganic perovskite has formula A′₁₋ₓ A BXₓ₃ with:
A′ an inorganic cation or an alloy of inorganic cations, preferably selected from among Cs, Rb, K and Na,
A a monovalent organic cation or an alloy of monovalent organic cations, preferably selected from among methylammonium (MA), formamidinium (FA), guanidinium (GA), dimethylammonium (DA), and imidazolium (IA), even more preferably A corresponds to MA and/or FA,
B an inorganic cation or an alloy of inorganic cations, preferably selected from among Pb, Sn, and Ge,
X one or a plurality of halogens, preferably selected from among Cl, Br, I, and F.

Advantageously, the hybrid organic-inorganic perovskite has formula Cs₁₋ₓMAₓPb(I_{1-y}Br_{y})₃, Cs₁₋ₓFAₓPb(I_{1-y-z}Br_{y}Cl_{z})₃ or Cs₁₋ₓFAₓPb(I_{1-y}Br_{y})₃, Cs₁₋ₓFAₓPb_{0.5}Sn_{0.5}(I_{1-y}Br_{y})₃, Cs_{1-x-z}MAₓFA_{z}Pb(I_{1-y}Br_{y})₃, or Cs_{1-x-z}MAₓFA_{z}Pb₁₋ₖSnₖ(I_{1-y}Br_{y})₃ with 0≤y≤1, 0≤k≤1, 0≤x≤1, 0≤z≤1 and 0≤x+z≤1, and preferably 0<y<1 and 0<x<1.

Advantageously, the powder of organic precursors comprises particles of formula AX with A representing a monovalent organic cation or an alloy of monovalent organic cations, preferably MA and/or FA, X representing one or a plurality of halogens selected from among Cl, Br, I, and F. Further, A represents an alloy of monovalent organic cations and/or X represents a plurality of halogens.

Advantageously, the powder of organic precursors is a FA(I_{1-y}Br_{y}) powder or a MA(I_{1-y}Br_{y}) powder with 0<y<1. Such powders can be formed by mechanosynthesis, respectively, from a FAI powder and from a FABr powder or from a MAI powder and from a MABr powder.

Advantageously, the layer comprising the inorganic precursors is a layer containing Pb, Cs, and one or a plurality of halogens selected from among iodine, bromine, and chlorine.

For example, the layer of inorganic precursors is a layer of PbI₂ and of CsI, a layer of PbI₂ and of CsBr, a layer of PbBr₂ and of CsI, a layer of PbBr₂ and of CsBr, a layer of PbI₂, PBBr₂, and CsI, a layer of PbI₂, PBBr₂, and CsBr, a layer of PbI₂, CsI, and CsBr, a layer of PbBr₂, CsI, and CsBr, or a layer of PbBr₂, PbI₂, CSI, and CsBr. It preferably is PbI₂ and CsBr or PbI₂ and CsI.

Advantageously, the powder of organic precursors may be in the form of an integral target or of a bed of powders.

According to an advantageous alternative embodiment, the layer of inorganic precursors is formed by thermal evaporation or spin coating.

According to another advantageous alternative embodiment, the layer of inorganic precursors is formed by CSS.

Advantageously, the substrate is a substrate adapted to the photovoltaic field. For example, it may be a glass, plastic, or metal substrate.

Advantageously, the substrate is a silicon substrate, preferably a textured silicon substrate. Such a substrate is particularly advantageous to form a photovoltaic device.

The invention also concerns a method of manufacturing a multi-junction photovoltaic cell comprising at least one perovskite photovoltaic cell or a single-junction perovskite photovoltaic cell, the method comprising the producing of an organic-inorganic perovskite layer according to the process such as previously described.

The multi-junction photovoltaic cell comprising at least one perovskite photovoltaic cell is, for example, a perovskite-silicon tandem photovoltaic cell, a perovskite-perovskite tandem photovoltaic cell, a perovskite-perovskite-silicon triple-junction photovoltaic cell, or a perovskite-perovskite-perovskite triple-junction photovoltaic cell.

### BRIEF DESCRIPTION OF THE DRAWINGS

The foregoing features and advantages, as well as others, will be described in detail in the rest of the disclosure of specific embodiments given as an illustration and not limitation with reference to the accompanying drawings, in which:

FIG. 1 schematically shows in cross-section a portion of a close space sublimation furnace according to a specific embodiment of the invention;

FIG. 2 schematically shows in cross-section a close space sublimation furnace according to another specific embodiment of the invention;

FIGS. 3A and 3B are schematic cross-section views, respectively, of a single-junction photovoltaic cell and of a tandem photovoltaic cell, according to different specific embodiments of the invention;

FIG. 4 is a graph showing X-ray diffractograms of a FA(I_{1-y}Br_{y}) powder with y˜0.5 obtained by mechanosynthesis according to a specific embodiment of the invention, as well as of an FAI powder, of an FABr powder, and of a powder obtained by simple mixture of FAI and FABr, the latter being given for comparison.

### DESCRIPTION OF EMBODIMENTS

Like features have been designated by like references in the various figures. In particular, the structural and/or functional features that are common among the various embodiments may have the same references and may dispose identical structural, dimensional and material properties.

For clarity, only those steps and elements which are useful to the understanding of the described embodiments have been shown and are described in detail.

In the following description, where reference is made to absolute position qualifiers, such as “front”, “back”, “top”, “bottom”, “left”, “right”, etc., or relative position qualifiers, such as “top”, “bottom”, “upper”, “lower”, etc., or orientation qualifiers, such as “horizontal”, “vertical”, etc., reference is made unless otherwise specified to the orientation of the drawings.

Unless specified otherwise, the expressions “about”, “approximately”, “substantially”, and “in the order of” signify plus or minus 10%, preferably of plus or minus 5%.

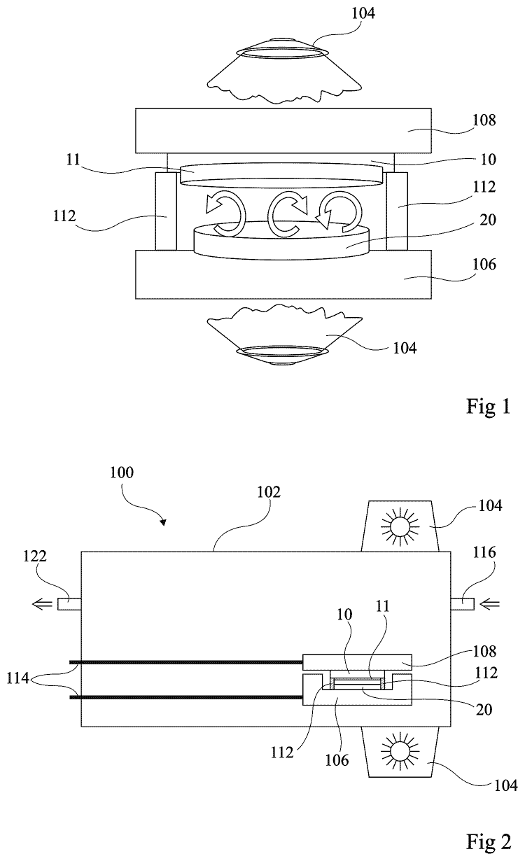

The process which will be described hereafter in more detail, referring to FIGS. 1 and 2, concerns the production of a hybrid organic-inorganic perovskite layer.

The hybrid organic-inorganic perovskite preferably has general formula A′₁₋ₓABXₓ₃ with:
A′ an inorganic cation or an alloy of inorganic cations, preferably selected from among Cs, Rb, K, and Na,
A a monovalent organic cation or an alloy of monovalent organic cations, preferably selected from among CH₃NH₃⁺ (methylammonium or MA), CH(NH)₂₂⁺ (formamidinium or FA), C(NH₂)₃⁺ (guanidinium or GA), C₂H₈N (dimethylammonium or DA), C₃H₅N₂ (imidazolium or IA); an alloy of monovalent organic cations may be, for example, MA₁₋ₓFAₓ with 0<x<1),
B an inorganic cation or an alloy of inorganic cations, preferably selected from among Pb, Sn, and Ge,
X one or a plurality of halogens, preferably selected from among Cl, Br, I, and F.

Preferably, A′ represents Cs.

Preferably, A represents MA and/or FA.

Preferably, B represents Pb, Sn, and Ge,

Preferably, X represents Br and/or I.

Advantageously, the hybrid organic-inorganic perovskite has formula Cs₁₋ₓMAₓPb(I_{1-y}Br_{y})₃, Cs₁₋ₓFAₓPb(I_{1-y-z}Br_{y}Cl_{z})₃ or Cs₁₋ₓFAₓPb(I_{1-y}Br_{y})₃ or Cs₁₋ₓFAₓPb_{0.5}Sn_{0.5}(I_{1-y}Br_{y})₃ or Cs_{1-x-z}MAₓFA_{z}Pb(I_{1-y}Br_{y})₃ or Cs_{1-x-z}MAₓFA_{z}Pb₁₋ₖSnₖ(I_{1-y}Br_{y})₃ with 0≤y≤1, 0≤k≤1, 0≤x<1, 0≤z≤1 et 0<x+z≤1, and preferably 0<y<1 and 0<x<1.

The process comprises the following steps:
a) Forming of a layer of inorganic precursors 11 on a substrate 10,
b) Implementation of a close space sublimation step based on a powder 20 comprising the organic precursors, powder 20 being obtained by mechanosynthesis, the distance between the powder of organic precursors 20 and substrate 10 being, for example, in the range from 0.1 to 5 mm, whereby the organic precursors react with the layer of inorganic precursors 11 and a hybrid organic-inorganic perovskite layer is formed (FIGS. 1 and 2).

The powder 20 used at step b) is prepared during a step, prior to step b), for example between step a) and step b), or preferably before step a).

The preparation of powder 20 is performed according to the following sub-steps:
providing at least a first group of particles of a first material and a second group of particles of a second material,
performing a mechanosynthesis sub-step by co-grinding at least of the first group of particles and of the second group of particles, until forming a third group of particles of a third material.

The final powder 20 predominantly comprises, and preferably consists of, the third group of particles. The composition of these particles corresponds to the composition to be reacted with the layer of precursors deposited during step a).

The mechanosynthesis sub-step is thus performed by co-grinding of a plurality of powders.

The co-grinding is carried out with at least two groups of particles. It could also be implemented with more than two groups of particles (for example three or four groups of particles).

The mechanosynthesis sub-step comprises performing a high-energy co-grinding of the pure or pre-alloyed materials in a high-energy mill to obtain a powder 20 having single-phase or multi-phase particles. Preferably, the particles are single-phase.

The co-grinding is performed in a planetary ball mill. The mass of balls is at least twice greater than the mass of powders, for example at least 15 times greater.

The rotation speed of the grinding is high (typically from 100 rpm to 700 rpm, for example 500 rpm). It depends on the mill used as well as on the mass of balls and of powders. The grinding time is for example between 10 min and 5 h, for example 1h.

The mixture may be an equimolar mixture.

The powder of organic precursors obtained by mechanosynthesis comprises, and preferably consists of, particles having general formula AX where A is a monovalent organic cation or an alloy of monovalent organic cations, preferably MA and/or FA, X representing one or a plurality of halogens selected from among Cl, Br, I, and F. In this general formula, A represents an alloy of monovalent organic cations and/or X represents a plurality of halogens.

Preferably, A is an alloy of monovalent organic cations and X is an alloy of halogens.

From this powder, it is possible by CSS to synthesize a perovskite layer of general formula A′₁₋ₓAₓBX₃ where A′ is an alloy of inorganic cations (Cs, Rb, K, Na), 0<x<1, and B a cation (Pb) or alloy of inorganic cations (Pb, Sn, Ge).

According to a specific embodiment, organic precursor powder 20 comprises MA(I_{1-y}Br_{y}) particles with 0<y<1. The powder is obtained by mechanosynthesis from MAI and MABr. It may, for example, be used to form layers of Cs₁₋ₓMAₓPb(I_{1-y}Br_{y})₃.

According to another specific embodiment, it is possible, for example, to obtain a powder 20 of MA_{z}FA_{1-z}I_{1-y}Br_{y} (with 0<z<1 and 0<y<1) from MABr and/or MAI and/or FABr and/or FAI powders. The mechanosynthesis of these powders enables to form, for example, layers of CsₓMA_{z}FA_{1-z-x}Pb(I_{1-y}Br_{y})₃.

According to another specific embodiment, it is possible to use FAI and/or FABr and/or FACl powders to form powders 20 of FAI_{1-y-z}Br_{y}Cl_{z} (with 0<y<1 and 0<z<1) for example to form Cs layers₁₋ₓ FAₓ Pb(I_{1-y-z}Br_{y}Cl_{z})₃.

The resulting powder 20 may be used as is, in particular in the form of a powder bed.

According to an advantageous alternative embodiment, the obtained powder 20 is used to manufacture a solid target (also known as a wafer). For this purpose, powder 20 is pressed, for example with a hydraulic press with P˜1×10⁷ Pa). The pressing of the target may be performed by heating the powder.

At step a), inorganic perovskite precursors are deposited on substrate 10 to form a layer 11 of inorganic precursors. Preferably, the precursors contain lead and cesium. Lead halides and cesium halides are advantageously used.

Preferably, the inorganic precursors are selected from among the following materials: CsCl, CsBr, CsI, PbCl₂, PbBr₂, and PbI₂, preferably with at least one Cs halide and one Pb halide. It may be a combination of two, three, or more than three precursors.

For example, the inorganic precursors are selected from among one of the following combinations: a combination of two materials such as PbI₂ and CsI, PbI₂ and CsBr, PbBr₂ and CsI, PbBr₂ and CsBr, or a combination of three materials PbI₂, PBBr₂, and CsI or PbI₂, PBBr₂, and CsBr or PbI₂, CSI, and CsBr or PbBr₂, CSI, and CsBr or a combination of four materials PbBr₂, PbI₂, CSI, and CsBr. Preferably, it is PbI₂ and CsBr or PbI₂ and CsI.

The layer of inorganic precursors 11 is, for example, deposited by thermal evaporation or spin coating.

According to a specific embodiment, the layer of inorganic precursors 11 can also be deposited by CSS.

The layer of inorganic precursors 11 has a thickness a few hundred nanometers, for example 300 nm.

The substrate used may be a substrate made of glass, of polymer (polyimide, for example), of steel. Preferably, it is made of silicon. The silicon substrate may be textured or non-textured. It may also be polished.

Advantageously, the substrate is functionalized with a layer or a stack of insulating, conductive, or semiconductor layers to inject and/or to collect charges in the perovskite material.

The second step comprises reacting the layer of inorganic precursors 11 with the organic precursors to form the perovskite. This step is performed by CSS.

The substrate 10 covered by the layer 11 of inorganic precursors is positioned opposite the powder 20 of organic precursors (powder bed or target formed of agglomerated particles).

The assembly is heated under vacuum (for example 50-100 Pa). The distance between the powder of organic precursors 20 and substrate 10 is, for example, in the range from 0.1 to 5 mm.

The organic precursors change state and pass in gaseous form (represented by arrows in FIG. 1) and they react with the layer of inorganic precursors 11 to form the hybrid organic-inorganic perovskite material.

Step b) is carried out in a close space sublimation furnace.

A lamp furnace may be used to carry out this step.

For example, as shown in FIG. 2, CSS furnace 100 comprises a reactor 102 around which is positioned a heating system. For example, it may be lamps 104 (FIG. 2) or any other heating system (resistor, for example).

Reactor 102 may be made of quartz, of graphite, or of metal.

Reactor 102 may be tubular.

As shown in FIGS. 1 and 2, furnace 100 also comprises a susceptor 106 (also called source block) and a cover 108 (also called substrate block). Susceptor 106 and cover 108 are made of thermally-conductive materials capable of withstanding pressure, vacuum, and high temperatures. They are preferably made of graphite.

Substrate 10 and target 20 are positioned between susceptor 106 and cover 108.

Preferably, substrate 10 is in direct contact with cover 108, which maintains its temperature at the set point value.

The powder of organic precursors 20 is arranged on susceptor 106.

Substrate 10 is at a short distance from powder 20. By short distance, there is meant a distance typically from 0.1 mm to 20 mm, preferably from 1 mm to 7 mm, for example from 0.1 mm to 5 mm or from 3 mm to 5 mm. In particular, a 1-mm distance may be selected.

One or a plurality of spacers 112, which may be made of a thermally-insulating material (for example glass, quartz, or alumina), are used to keep substrate 10 at a short distance from powder 20.

Cover 108 may be held flat against the substrate by a fastening system in susceptor 106, not shown (for example, a screw or any other fastening system).

Susceptor 106 and cover 108 each have a thermocouple 114 or any other system (pyrometer, etc.) for measuring and controlling their temperature.

A heating system (lamp, resistors, . . . ) enables to regulate the temperature of susceptor 106 (Ttarget) and of cover 108 (Tsubstrate) in a range which may span from 20° C. to 600° C. Temperature rise ramps are controllable in a range, for example, from 0.1° C./s to 10° C./s. Susceptor 106 (Ttarget) and cover 108 (Tsubstrate) may be independently controlled by temperature ramps (or sequences of ramps). Thus, it is possible to adjust the sublimation kinetics of powder 20 and the reaction temperatures with the inorganic layer deposited on substrate 10 to control the layer morphology and/or the duration of the process.

Device 100 is coupled to an inlet 116 for inert gas (such as argon or N₂).

Device 100 may also be coupled to an inlet for oxidizing gas (such as O₂) or a to an inlet for reducing gas (such as H₂).

Device 100 comprises a gas outlet 122, coupled to a pumping system enabling to achieve a vacuum Pfurnace ranging, for example, from 0.00001 Pa to 1 Pa. Value Pfurnace depends on the CSS furnace used.

During step b), the target is sublimated. The deposition by sublimation is performed by heating susceptor 106 and cover 108 under vacuum.

During step b), the temperature of the target may be identical to the substrate temperature.

According to an alternative embodiment, during step b), the substrate temperature Tsub is advantageously lower than the target temperature Ttarget, in order to create a thermal gradient while favoring a higher partial pressure of the organic compound without risking decomposing the perovskite. Temperature difference Ttarget-Tsub is from 1° C. to 350° C. (for example from 1 to 100° C., in particular 20° C.), preferably from 50° C. to 300° C. and even more preferably from 100° C. to 250° C., for example 150° C.

According to another alternative embodiment, during step b), Ttarget<Tsubstrate to favor the condensation of vapor on the substrate and thus accelerate the reaction. The temperature difference may be from 1 to 100° C., for example 20° C.

The targeted temperatures depend on the material to be sublimated.

The obtained perovskite layers may be used in many industrial fields, in particular in the field of X-ray detection for medical applications, safety, security, radioprotection, and large-scale scientific instruments, but also in the field of photovoltaics, of gamma detection radiation, of ionizing radiation (alpha, beta, neutron), or also for the manufacturing of electronic, optical, and optoelectronic devices, in particular for the manufacturing of light-emitting diodes (LEDs), of photodetectors, of scintillators, or also of transistors.

In particular, the process applies to deposit hybrid organic-inorganic perovskites of low thicknesses (in the range from 10 nm to 5,000 nm). These materials are generally used for visible or near-infrared optical applications. Photovoltaic applications will in particular be mentioned, but also infrared and near-infrared detection or light emission in the visible, near-infrared, and infrared wavelengths.

Advantageously, as concerns photovoltaic applications, the previously-described process may be used to produce a layer of hybrid organic-inorganic perovskite material in a photovoltaic cell.

By varying the amount of iodine and of bromine in the perovskite material, it is possible to modify the bandgap energy.

The photovoltaic cells may be single-junction or multi-junction cells.

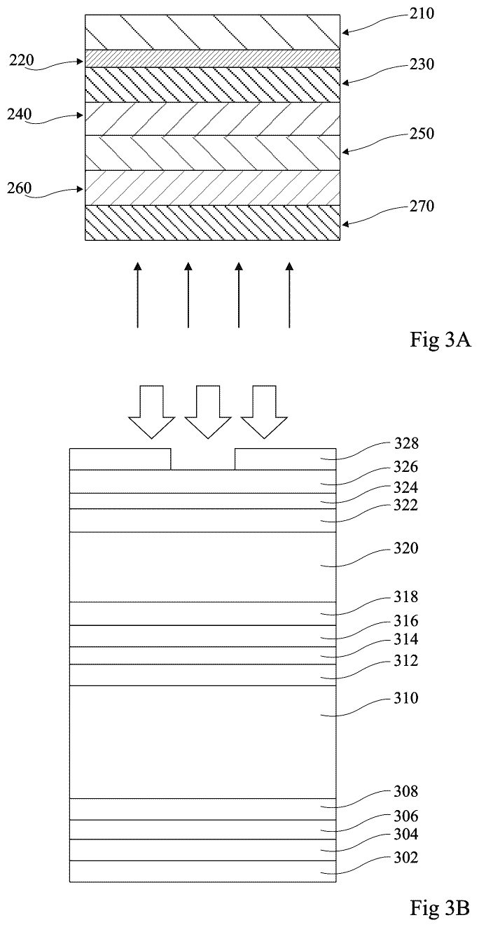

For example, a single-junction p-i-n photovoltaic cell may comprise, from the rear surface to the front surface (FIG. 3A):
a top electrode 210,
a buffer layer 220,
an n-type layer 230,
an active perovskite layer 240,
a p-type layer 250,
a transparent conductive oxide layer 260,
a substrate 270.

Preferably, the photovoltaic cell is made up of the various elements mentioned hereabove.

The front surface of the photovoltaic cell is intended to receive a luminous flux.

The incident radiation is represented by arrows in FIG. 3A.

Upper electrode 210 is made, for example, of Ag, Cu, Ni, Al.

Buffer layer 220 may be a layer made of LiF, SnS, metal oxide, or of BCP (bathocuproine).

N-type layer 230 may, for example, be made of C60, PC61BM ([6,6]-phenyl-C61-methyl butanoate or “[6,6]-phenyl-C61-butyric acid methyl ester”), PC71BM ([6,6]-phenyl-C71-methyl butanoate or “[6,6]-phenyl-C71-butyric acid methyl ester”), PCBM/C60, or PCBM/C. Preferably, it is made of C60.

According to other alternative embodiments, n-type layer 230 may be an oxide layer, for example SnOx (with x between 1 and 2), ZnO, Al:ZnO, ITO, or IZO.

Active layer 240 is an active perovskite layer obtained by the previously-described process. Preferably, the perovskite layer is a perovskite of APbX₃ type, with A representing methylammonium, dimethylammonium, formamidinium, guanidinium, or cesium cations (the above-mentioned cations may be used alone or in a mixture) and X representing halide anions (preferably chlorine, bromine, iodine anions, alone or in a mixture).

Active layer 240 has, for example, a thickness in the range from 200 nm to 1.5 μm.

According to a first variant, p-type 250 layer may be a poly(3,4-ethylenedioxythiophene) (PEDOT) or poly[bis(4-phenyl)(2,4,6-trimethylphenyl)amine (PTAA) layer.

According to a second variant, p-type 250 layer is a self-assembled monolayer (SAM). The SAM layer may be a layer of 2PACz (2-(9H-Carbazol-9-yl)ethyl]phosphonic acid), 3PACz (3-(9H-carbazol-9-yl)propyl)phosphonic acid), 4PACz (4-(9H-carbazol-9-yl)butyl)phosphonic acid), Me-4PACz (4-(3,6-Dimethyl-9H-carbazol-9-yl)butyl)phosphonic acid), MeO-2PACz (2-(3,6-Dimethoxy-9H-carbazol-9-yl)ethyl)phosphonic acid), 6dPA (1,6-hexylenediphosphonic acid), or also a layer of MPA (methylphosphonic acid) or a layer obtained from a mixture of these molecules. It may also be one of their derivatives.

According to a third variant, p-type layer 250 is an oxide layer, for example a MoOₓ layer, a NiOₓ layer.

According to another variant, p-type layer 250 may be an oxide/SAM bilayer, for example a NiOₓ/SAM bilayer.

Transparent conductive oxide layer 260 may be an indium-tin oxide (ITO) layer.

These various elements are positioned on a substrate 270 on the rear surface. Substrate 270 is, for example, made of glass.

A tandem Si/perovskite photovoltaic cell will now be described in more detail. Such a cell comprises a lower sub-cell made of silicon (Si) and an upper sub-cell made of perovskite (PK).

Such a cell is for example shown in FIG. 3B. This structure is said to be of “reverse” or p-i-n type. The cell comprises, from the rear surface to the front surface:
a first electrode 302,
a first transparent conductive oxide layer 304, for example made of ITO or AZO,
a layer of p-doped amorphous silicon 306,
optionally an intrinsic amorphous silicon layer 308,
an active crystalline silicon layer 310,
optionally an intrinsic amorphous silicon layer 312,
a layer of n-doped amorphous silicon 314,
a second layer of transparent conductive oxide 316, for example made of ITO or AZO,
a p-type layer (HTL) 318, for example made of PEDOT, PTAA, or also of an oxide (MoOₓ or NiOₓ for example) or formed of a SAM,
an active layer of perovskite 320, for example of formula APbX₃,
a passivation layer, for example MgFx, AlOx, LiF,
an n-type layer (ETL) 322, for example made of C₆₀,
a buffer layer 324, for example made of BCP or of an oxide such as SnOₓ,
a third layer of transparent conductive oxide 326, for example made of ITO or AZO,
a second electrode 328, for example made of Ag, Cu, Ni, or Al.

The various materials used for the upper perovskite (PK) sub-cell may for example be selected from the materials previously described for the single-junction cell.

The CSS deposition method is particularly adapted to forming perovskite-based solar cells on a lower Si cell. The lower cell may have a textured surface (for example a pyramid-shaped surface with a height from 1 to 2 μm). In the case of tandem cells on Si, it may in particular be Cs₁₋ₓFAₓPb(I_{1-y}Br_{y})₃ perovskite with 0.65<x<0.9 (preferably x˜0.8) and y˜0.3. The Br rate may be easily adjusted to obtain an energy bandgap at 1.7 eV (that is, 0.2<y<0.4).

For photovoltaic applications, the perovskite layer production process may also be used to manufacture single-junction solar cells based on perovskite. In this case, the perovskite will have a bandgap energy in the range from 1.3 eV to 1.5 eV. In particular, it may be Cs₁₋ₓFAₓPb(I_{1-y}Br_{y})₃ perovskite with x˜0.85 and 0.05<y<0.25.

It is also possible to manufacture a perovskite (1.2 eV)/perovskite (1.8 eV) tandem cell by depositing a first Cs₁₋ₓFAₓPb_{0.5}Sn_{0.5}(I_{1-y}Br_{y})₃ perovskite with x˜0.85 and y˜0.05 and a second Cs₁₋ₓFAₓPb(I_{1-y}Br_{y})₃ one with x˜0.85 and y˜0.5. One of the perovskite layers or both perovskite layers may be formed according to the previously-described process.

Various embodiments and variants have been described. Those skilled in the art will understand that certain features of these various embodiments and variants may be combined, and other variants will occur to those skilled in the art.

Finally, the practical implementation of the described embodiments and variants is within the abilities of those skilled in the art based on the functional indications given hereabove.

### Illustrative and Non-Limiting Example of a Specific Embodiment of the Invention

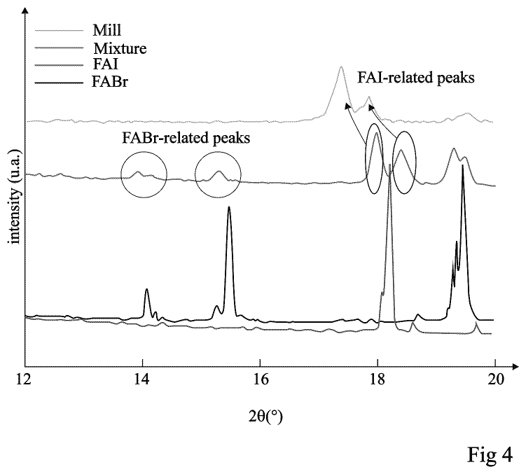

In this example, the mechanosynthesis step is performed by co-grinding of an equimolar mixture of FAI and FABr powders in a planetary mill for 1 h at 500 rpm. The m_{powder}/m_{balls} mass ratio is lower than 0.2. A characterization by X-ray diffraction (FIG. 4) shows that only the peaks related to FAI are visible. They are largely shifted leftwards.

The absence of peaks related to FABr jointly with the shift of the FAI peaks proves that Br has inserted into the FAI mesh to form a solid FA(I_{1-y}Br_{y}) solution.

As a comparison, X-ray diffraction on a mixture of powders shows that the signature of FAI and of FABr is visible. This confirms that both phases (FAI and FABr) effectively coexist in the powder mixture.

A hybrid organic-inorganic perovskite layer has been deposited by CSS from a FA(I_{1-y}Br_{y}) powder with 0<y<1 obtained by mechanosynthesis.

The powder used may be in the form of a solid CSS target, or it is also possible to arrange a bed of powder in the CSS furnace rather than a solid target.

A plurality of hybrid organic-inorganic perovskite layers of formula Cs₁₋ₓFAₓPb(I_{1-y}Br_{y})₃ have been formed according to the following steps:
a) deposition of the inorganic precursors (PbI₂+CsBr) on a substrate to form inorganic layers with a thickness of approximately 250 nm containing PbI₂ and CsBr,
b) step of CSS from a FA (I_{1-y}Br_{y}) powder obtained by mechanosynthesis to form the Cs₁₋ₓFAₓP(I_{1-y}Br_{y})₃ perovskite from the previously-deposited precursors.

As a comparison, perovskites have also been formed from a target formed of simply mixed powders.

The various perovskites obtained (from the powder mixture or from the powder obtained by mechanosynthesis) have been characterized by X-ray diffraction to determine the Br content in the Cs₁₋ₓFAₓPb(I_{1-y}Br_{y})₃ perovskite. This rate may be determined relative to the offset of peak (101) at 13.9° of the perovskite structure.

They also have been characterized by UV-Vis spectrometry to determine the value of the bandgap of the perovskite.

The results are listed in the following table:

TABLE 1

| | [FABr]/ | | | | |
|---|---|---|---|---|---|
| | ([FAI] + | | | | |
| | [FABr]) in the | CSS | CSS | Value | |
| | CSS target | T° | duration | y | Band gap |
| powder mixture | 12.5% | 125° C. | 40 min | ~18% | 1.63 eV |
| powder | 50% | 140° C. | 10 min. | ~21% | 1.66 eV |
| mechanosynthesis | | | | | |

The FABr content of the target obtained by mechanosynthesis had to be increased as compared with that of the target obtained by simple mixing of powders. Indeed, in the case of mixed powders, FABr sublimating at lower temperatures, it preferentially reacts to form the perovskite. With the mechanosynthesis step, the obtained powder being an alloy at an atomic scale, the gas phase contains the same level of Br and I as the target. To obtain the same quantity of Br in the gas, its rate in the target has to be increased. The mass of the target is unchanged.

In the case of the target obtained by mechanosynthesis, the process temperature could be increased from 125° C. to 140° C., and the process has thus been shortened from 40 min to 10 min, which is a considerable advantage to apply the process at a large scale.

The properties of the layers in terms of crystallographic quality, Br ratio, and bandgap energy are similar.

Hybrid organic-inorganic perovskite layers have been deposited on textured silicon substrates to form tandem cells on Si.

In the case of a layer formed from a target obtained by FAI+FABr mixing, a characterization by X-ray diffraction shows the presence of an iodine-rich perovskite phase and of a bromine-rich perovskite phase. In the case of a layer formed from an FAI_{1-y}Br_{y} powder target obtained by mechanosynthesis, a characterization by X-ray diffraction confirms the presence of a single perovskite phase with a halogen composition equivalent to that of the target.

1. Process for producing an organic-inorganic perovskite layer comprising the following steps:
Forming of a layer of inorganic precursors on a substrate,
Implementation of a close space sublimation step from an powder of organic precursors, whereby the vapors of the powder of organic precursors react with the layer of inorganic precursors and a hybrid organic-inorganic perovskite layer is formed,
wherein the powder of organic precursors is obtained by mechanosynthesis by co-grinding at least a first group of particles of a first material and a second group of particles of a second material, until forming a third group of particles of a third material, the third group of particles forming the powder of organic precursors.

2. Process according to claim 1, wherein the hybrid organic-inorganic perovskite has formula A′₁₋ₓABXₓ₃ with:
A′ an inorganic cation or an alloy of inorganic cations, selected from among Cs, Rb, K, and Na,
A a monovalent organic cation or an alloy of monovalent organic cations, preferably selected from among methylammonium, formamidinium, guanidinium, dimethylammonium, and imidazolium, even more preferably A corresponds to MA and/or FA,
B an inorganic cation or an alloy of inorganic cations selected from among Pb, Sn, and Ge,
X one or a plurality of halogens selected from among Cl, Br, I, and F.

3. Process according to claim 1, wherein the powder of organic precursors comprises particles of formula AX with A representing a monovalent organic cation or an alloy of monovalent organic cations, preferably MA and/or FA, X representing one or a plurality of halogens selected from among Cl, Br, I, and F and wherein A represents an alloy of monovalent organic cations and/or X represents a plurality of halogens.

4. Process according to claim 1, wherein the hybrid organic-inorganic perovskite has formula Cs₁₋ₓMAₓPb(I_{1-y}Br_{y})₃, Cs₁₋ₓFAₓPb(I_{1-y-z}Br_{y}Cl_{z})₃, Cs₁₋ₓFAₓPb(I_{1-y}Br_{y})₃, Cs₁₋ₓFAₓPb_{0.5}Sn_{0.5}(I_{1-y}Br_{y})₃, Cs_{1-x-z}MAₓFA_{z}Pb(I_{1-y}Br_{y})₃ or Cs_{1-x-z}MAₓFA_{z}Pb₁₋ₖSnₖ(I_{1-y}Br_{y})₃ with 0≤y≤1, 0≤k≤1, 0≤x≤1, 0≤z≤1, and 0≤x+z≤1.

5. Process according to claim 1, wherein the layer comprising the inorganic precursors is a layer containing Pb, Cs, and one or a plurality of halogens selected from among iodine, bromine, and chlorine.

6. Process according to claim 1, wherein the powder of organic precursors is a FA(I_{1-y}Br_{y}) powder or a MA(I_{1-y}Br_{y}) powder with 0<y<1.

7. Process according to claim 1, wherein the powder of organic precursors is in the form of an integral target or of a bed of powders.

8. Process according to claim 1, wherein layer of inorganic precursors is formed by thermal evaporation or spin coating.

9. Process according to claim 1, wherein the layer of inorganic precursors is formed by close space sublimation.

10. Process according to claim 1, wherein the substrate is a glass, plastic, metal, or silicon substrate, preferably a textured silicon substrate.

11. Method of manufacturing a single-junction perovskite photovoltaic cell or a multi-junction photovoltaic cell comprising at least one perovskite photovoltaic cell, for example a perovskite-silicon tandem photovoltaic cell, a perovskite-perovskite tandem photovoltaic cell, a perovskite-perovskite-silicon triple junction photovoltaic cell, or a perovskite-perovskite-perovskite triple junction photovoltaic cell, the process comprising the production of an organic-inorganic perovskite layer according to the process according to claim 1.
